(19) United States
(12) Patent Application Publication
(10) Pub. No.: US 2025/0046701 A1
(43) Pub. Date: Feb. 6, 2025

(54) PACKAGE STRUCTURE HAVING AIR GAP

(71) Applicant: RF MATERIALS CO., LTD., Ansan-si (KR)

(72) Inventors: Ki Woo HAN, Seoul (KR); Won Shil KANG, Seoul (KR); Jin Young JEONG, Seoul (KR)

(21) Appl. No.: 18/706,744

(22) PCT Filed: Oct. 4, 2022
(86) PCT No.: PCT/KR2022/014915

§ 371 Date: May 2, 2024

(30) Foreign Application Priority Data
Nov. 4, 2021 (KR) 10-2021-0150615

(51) Int. Cl. H01L 23/498; H01L 23/13; H01L 23/14; H01L 23/66

(52) U.S. Cl. CPC H01L 23/49838; H01L 23/14; H01L 23/49822; H01L 23/66; H01L 23/13; H01L 2223/6605

(57) ABSTRACT

The present invention relates to a package structure having an air gap, comprising: a first substrate layer; a second substrate layer provided on top of the first substrate layer and having a signal line printed in a predetermined pattern at the center of the upper surface thereof and a ground printed in a predetermined pattern on one side and the other side of the signal lines; a third substrate layer provided on top of the signal line and the ground; a fourth substrate layer provided on top of the third substrate layer. The third substrate layer has an air gap formed at the center thereof, an upper portion of the air gap is in contact with one lower side of the fourth substrate layer, and a lower portion of the air gap is in contact with the signal line.

### CROSS REFERENCE TO RELATED APPLICATIONS

This application is a National Stage Entry of International Patent Application No. PCT/KR2022/014915, filed on Oct. 4, 2022, which claims priority from and the benefit of Korean Patent Application No. 10-2021-0150615, filed on Nov. 4, 2021, each of which is hereby incorporated by reference for all purposes as if fully set forth herein.

### BACKGROUND

### Field

The present disclosure relates generally to a package structure having an air gap. More particularly, the present disclosure relates to a package structure having an air gap, the package structure being capable of reducing dielectrics in an electric field by forming the air gap between a signal line and a ground plane and of transmitting ultra-wideband signals by reducing RF loss and significantly improving bandwidth due to reduced parasitic capacitor components.

### Discussion of Background

Generally, for high-frequency signals, waveguides with low loss are used rather than microstrip transmission lines with high loss. However, in some cases, in order to transmit high-frequency signals to a board with electronic components at a high frequency such as terahertz (THz), the board with electronic components is interconnected with waveguides, or electronic components connected with a microstrip transmission line are directly connected to a waveguide.

When interconnecting a waveguide and a microstrip board with electronic components, transmission loss occurs due to impedance mismatch because there is no device for impedance matching inside the waveguide.

Conventional techniques to suppress impedance mismatch include making the end of the waveguide into a step shape and adjusting the width and height of the step, or making a rectangular slot at the interconnection area to facilitate signal transition.

However, the above-mentioned conventional technique has complexity and difficulty in manufacturing due to a complex structure inside the waveguide. Also, impedance matching requires substantial experimental effort, making it difficult to achieve optimal impedance matching and degrading RF performance.

### SUMMARY

Accordingly, the present disclosure has been made keeping in mind the above problems occurring in the related art, and an objective of the present disclosure is to provide a package structure having an air gap, the package structure being capable of reducing dielectrics in an electric field by forming the air gap between a signal line and a ground plane and of transmitting ultra-wideband signals by reducing RF loss and significantly improving bandwidth due to reduced parasitic capacitor components.

The objectives of the present disclosure are not limited to those mentioned above, and other objectives not mentioned will be clearly understood by those skilled in the art from the description provided hereinafter.

In order to accomplish the above objective, one aspect of the present disclosure provides a package structure having an air gap, the package structure including: a first substrate layer, a second substrate layer provided on top of the first substrate layer and having a signal line printed in a predetermined pattern at a center of an upper surface thereof and a pair of grounds printed in a predetermined pattern at opposite sides of the signal line, respectively; a third substrate layer provided on top of the signal line and the grounds; and a fourth substrate layer provided on top of the third substrate layer. The air gap is formed at a center of the third substrate layer. An upper portion of the air gap is in contact with a side of a lower portion of the fourth substrate layer, and a lower portion of the air gap is in contact with the signal line.

In addition, the first substrate layer, the second substrate layer, the third substrate layer, and the fourth substrate layer may be made of a dielectric material.

In addition, the package structure may further include: a ground layer disposed between the first substrate layer and the second substrate layer.

In addition, the package structure may further include: a via provided below the signal line and the grounds. The via may penetrates the first substrate layer and the second substrate layer in a vertical direction.

In addition, the package structure may further include: a ground plane printed on a lower surface of the fourth substrate layer.

In addition, either a front or a rear surface of the air gap may be configured to be opened.

In addition, another aspect of the present disclosure provides a package structure having an air gap, the package structure including: a first substrate layer; a second substrate layer provided on top of the first substrate layer and having a signal line printed in a predetermined pattern at a center of an upper surface thereof and a pair of grounds printed in a predetermined pattern at opposite sides of the signal line, respectively; a third substrate layer provided on top of the signal line and the grounds; and a fourth substrate layer provided on top of the third substrate layer. The air gap is formed at a center of the third substrate layer. An upper portion of the air gap is in contact with a side of a lower portion of the fourth substrate layer, and a lower portion of the air gap is in contact with the signal line. The air gap extends in the front and rear direction of the third substrate layer along the signal line. A ground plane is printed on a lower surface of the fourth substrate layer, and the ground plane is disposed to face the signal line with the air gap therebetween.

According to a package structure having an air gap according to the present disclosure, by providing the air gap and a ground plane, it is possible to reduce dielectric loss while reducing dielectrics, thereby significantly improving RF performance and enabling transmission of ultra-wideband signals.

### BRIEF DESCRIPTION OF THE DRAWINGS

FIG. 1 is a perspective view illustrating a package structure having an air gap according to an embodiment of the present disclosure.

FIG. 2 is a bottom perspective view illustrating the package structure having the air gap according to the embodiment of the present disclosure.

FIG. 3 is an exploded perspective view illustrating the package structure having the air gap according to the embodiment of the present disclosure.

FIG. 4 is an exploded perspective view illustrating the package structure having the air gap according to the embodiment of the present disclosure.

FIG. 5 is a sectional view illustrating the package structure having the air gap according to the embodiment of the present disclosure.

FIG. 6 is a view illustrating simulation data confirming the voltage standing wave ratio (VSWR) and the |S₂₁| parameter in a conventional package structure.

FIG. 7 is a view illustrating simulation data confirming the voltage standing wave ratio (VSWR) and the |S₂₁| parameter in the package structure having the air gap according to the embodiment of the present disclosure.

### DETAILED DESCRIPTION

The above and other objectives, features, and advantages of the present disclosure will be clearly understood from the more particular description of exemplary embodiments of the present disclosure. The present disclosure may, however, be embodied in different forms and should not be construed as limited to the embodiments set forth herein.

Rather, these embodiments are provided so that this disclosure is thorough and complete and fully conveys the present disclosure to those skilled in the art.

The embodiments described and illustrated herein include their complementary embodiments.

As used herein, the singular forms are intended to include the plural forms as well, unless the context clearly indicates otherwise. It will be further understood that the terms “comprises” and/or “comprising” when used herein, do not preclude the presence or addition of one or more other elements. Hereinbelow, the present disclosure will be described in detail with reference to the accompanying drawings. In describing specific embodiments below, various specific contents have been prepared to more specifically describe the present disclosure and help understanding. However, it will be appreciated by a reader having enough knowledge in the art to understand the present disclosure that the present disclosure can be used without these various specific details. In some cases, it is mentioned in advance that parts that are commonly known and not highly relevant to the present disclosure in describing the in present disclosure are not described in order to avoid confusion in describing the present disclosure.

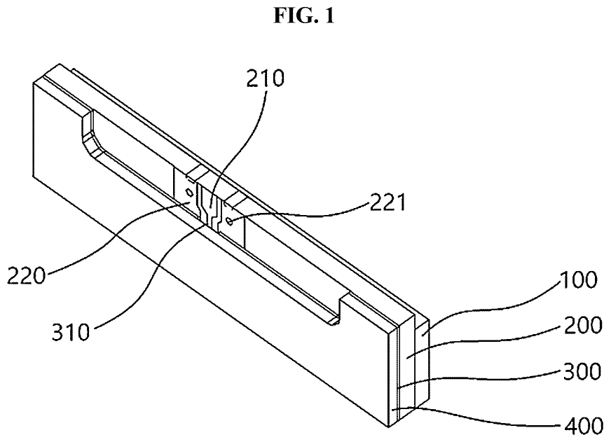

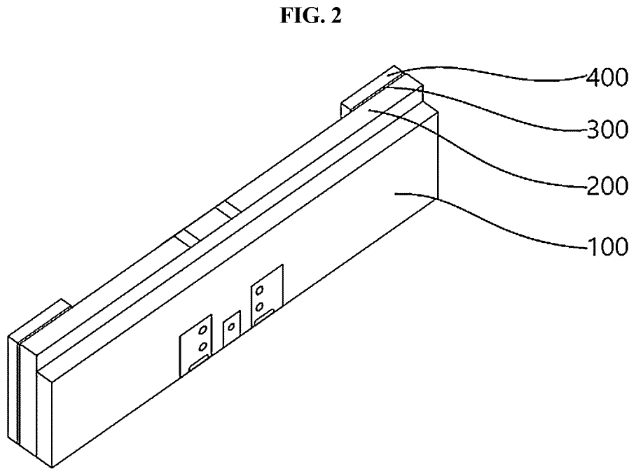

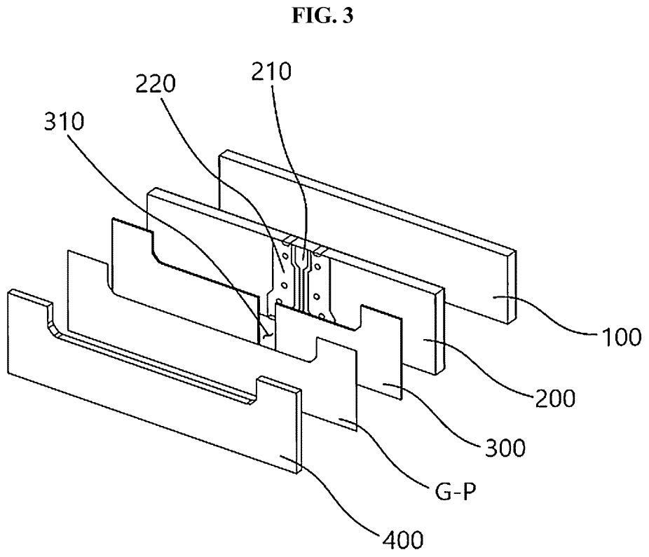

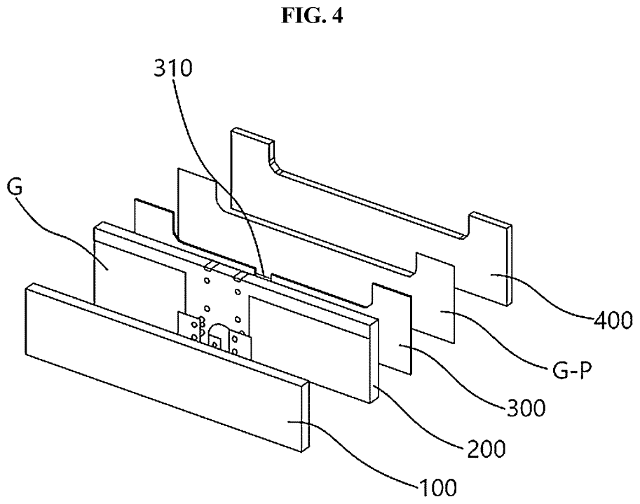

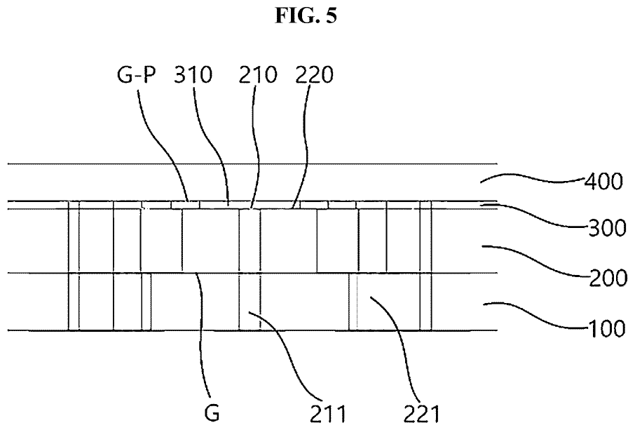

FIG. 1 is a perspective view illustrating a package structure having an air gap according to an embodiment of the present disclosure. FIG. 2 is a bottom perspective view illustrating the package structure having the air gap according to the embodiment of the present disclosure. FIG. 3 is an exploded perspective view illustrating the package structure having the air gap according to the embodiment of the present disclosure. FIG. 4 is an exploded perspective view illustrating the package structure having the air gap according to the embodiment of the present disclosure. FIG. 5 is a sectional view illustrating the package structure having the air gap according to the embodiment of the present disclosure.

As illustrated in FIGS. 1 to 5, the package structure having the air gap (QFN: QUAD FLAT NON-LEADED PACKAGE) according to the present disclosure largely includes a first substrate layer 100, a second substrate layer 200, a third substrate layer 300, and a fourth substrate layer 400.

More specifically, the package structure having the air gap includes the first substrate layer 100, the second substrate layer 200 provided on top of the first substrate layer 100 and having a signal line 210 printed in a predetermined pattern at a center of an upper surface thereof and a pair of grounds 220 printed in a predetermined pattern at opposite sides of the signal line 210, respectively, the third substrate layer 300 manufactured in a predetermined shape and provided on top of the signal line 210 and the grounds 220, and the fourth substrate layer 400 provided on top of the third substrate layer 300. The air gap 310 is formed at a center of the third substrate layer 300. An upper portion of the air gap 310 is in contact with a side of a lower portion of the fourth substrate layer, and a lower portion of the air gap is in contact with the signal line.

First, the first substrate layer 100 is located at the lowest layer of the package structure having the air gap according to the present disclosure.

The first substrate layer 100 is formed from a dielectric material.

Here, in one embodiment of the present disclosure, the first substrate layer 100 may be made of a ceramic material through processes such as mixing Al₂O₃ powder and manufacturing and cutting a sheet.

The first substrate layer 100 may transmit signals by being mounted on a PCB substrate or the like.

The second substrate layer 200 is provided on top of the first substrate layer 100, and has the signal line 210 printed in a predetermined pattern at the center of the upper surface thereof and the pair of grounds 220 printed in a predetermined pattern at the opposite sides of the signal line 210, respectively. The second substrate layer 200 is formed from a dielectric material.

Here, in one embodiment of the present disclosure, the second substrate layer 200 may be made of a ceramic material through processes such as mixing Al₂O₃ powder and manufacturing and cutting a sheet.

Meanwhile, the signal line 210 is printed on the upper surface of the second substrate layer 200. The printing of the signal line may be implemented using various printing methods, but in the present disclosure, it is preferable to use screen printing.

In addition, the pair of grounds 220 are printed in a predetermined pattern at the opposite sides of the signal line 210, respectively so as to be spaced apart from each other by a predetermined interval. The printing of the grounds may be implemented using various printing methods, but in the present disclosure, it is preferable to use screen printing.

Here, a via 211 is provided below the signal line 210. The via 211 penetrates the first substrate layer 100 and the second substrate layer 200 in the vertical direction and may be mounted on a PCB substrate or the like to transmit signals.

Here, the via 211 is formed by filling a through groove penetrating the first substrate layer 100 and the second substrate layer 200 in the vertical direction with a filler. As the filler, various fillers such as tungsten, gold, silver, or copper may be used.

In addition, a via 221 is provided below the grounds 220. The via 221 penetrates the first substrate layer 100 and the second substrate layer 200 in the vertical direction and may be mounted on a PCB substrate or the like.

Here, the via 221 is formed by filling a through groove penetrating the first substrate layer 100 and the second substrate layer 200 in the vertical direction with a filler. As the filler, various fillers such as tungsten, gold, silver, or copper may be used.

Meanwhile, a ground layer G may be further provided between the first substrate layer 100 and the second substrate layer 200.

Here, the signal line 210 and the via 211 may penetrate the first substrate layer 100, the second substrate layer 200, and the ground layer G in the vertical direction.

The third substrate layer 300 is provided on top of the signal line and the grounds.

As illustrated in FIGS. 1 to 4, the third substrate layer 300 is manufactured in a predetermined shape with a side bent inwardly, but the present disclosure is not limited thereto and may be manufactured in various shapes.

In addition, the third substrate layer 300 is formed from a dielectric material.

Here, in one embodiment of the present disclosure, the third substrate layer 300 may be made of a ceramic material through processes such as mixing Al₂O₃ powder and manufacturing and cutting a sheet.

Here, the air gap 310 is formed at the center of the third substrate layer 300. The upper portion of the air gap 310 is located in contact with the side of the lower portion of the fourth substrate layer 400, and the lower portion of the air gap 310 is located in contact with the signal line 210.

That is, as the upper portion of the air gap 310 is in contact with the lower portion of the fourth substrate layer 400 and the lower portion of the air gap 310 is in contact with the signal line 210, upper and lower surfaces of the air gap 310 are sealed.

Here, a conventional package structure implements a sealed structure. However, in the present disclosure, the air gap 310 needs to be filled with air, so either a front or rear surface of the air gap 310 may be opened and filled with air and then sealed by a separate sealing means.

Consequently, the air gap 310 according to the present disclosure can reduce dielectric loss while simultaneously reducing dielectrics along with a ground plane G-P, which will be described later, and thus significantly improve RF performance.

The fourth substrate layer 400 is provided on top of the third substrate layer 300.

As illustrated in FIGS. 1 to 4, the fourth substrate layer 400 is manufactured in a predetermined shape with a side bent inwardly, but the present disclosure is not limited thereto and may be manufactured in various shapes.

In addition, the fourth substrate layer 400 is formed from a dielectric material.

Here, in one embodiment of the present disclosure, the fourth substrate layer 400 may be made of a ceramic material through processes such as mixing Al₂O₃ powder and manufacturing and cutting a sheet, or may be made of a metal material.

Meanwhile, the ground plane G-P is printed on a lower surface of the fourth substrate layer 400.

The printing of the ground plane G-P may be implemented using various printing methods, but in the present disclosure, it is preferable to use screen printing.

That is, an electric field is generated between the signal line 210 and the ground plane G-P rather than between the signal line 210 and the grounds G, and there is no dielectrics between the signal line 210 and the ground plane G-P. Therefore, dielectric loss is reduced.

Consequently, the ground plane G-P according to the present disclosure can reduce dielectric loss while simultaneously reducing dielectrics along with the air gap 310 and thus significantly improve RF performance.

Hereinbelow, data simulated with the voltage standing wave ratio (VSWR) and the |S₂₁| parameter of the package structure with reduced dielectric loss according to the present disclosure will be described.

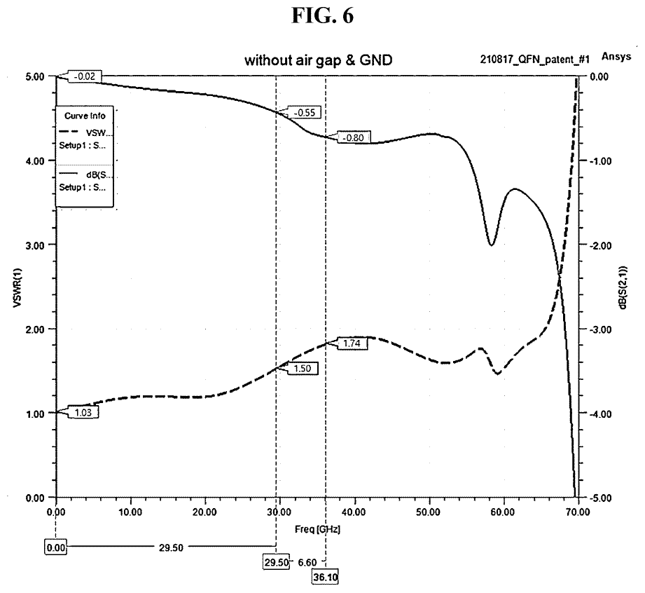

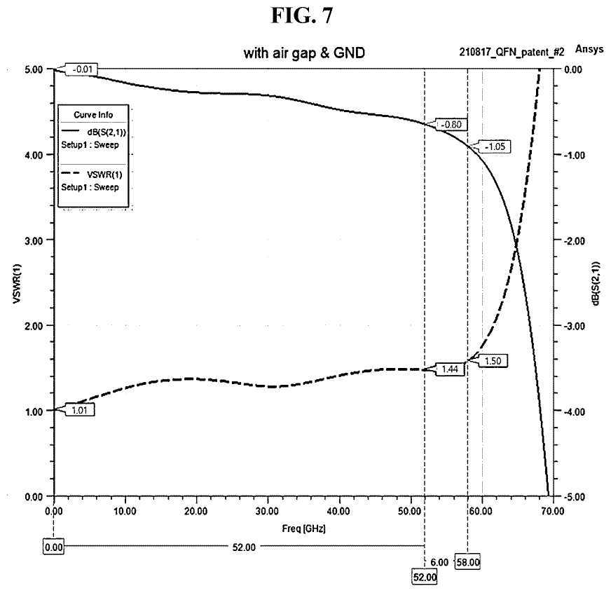

FIG. 6 is a view illustrating simulation data confirming the voltage standing wave ratio (VSWR) and the |S₂₁| parameter in a conventional package structure. FIG. 7 is a view illustrating simulation data confirming the voltage standing wave ratio (VSWR) and the |S₂₁| parameter in the package structure reduced dielectric loss according to the embodiment of the present disclosure.

First, the degree of reflection loss through impedance matching of the signal line can be determined through the voltage standing wave ratio (VSWR). The closer it is to 1, the less reflection there is, and the greater the reflection, the closer it is to infinity.

That is, it was confirmed that when the air gap 310 according to the present disclosure was applied, the frequency band with a VSWR of less than 1.5 increased by 98% from the existing range of 0 to 29.5 GHz to 0 to 58 GHz.

In addition, insertion loss of the signal line can be determined through the |S₂₁| parameter. The closer it is to 0, the smaller the loss.

That is, it was confirmed that when the air gap 310 according to the present disclosure was applied, the frequency band where with an |S₂₁| of less than 0.8 dB increased by about 44% from the existing range of 0 to 36.1 GHz to 0 to 52 GHz.

Therefore, according to the package structure with reduced dielectric loss according to the present disclosure, by providing the air gap and the ground plane, it is possible to reduce dielectric loss while reducing dielectrics, thereby significantly improving RF performance and enabling transmission of ultra-wideband signals.

Although the preferred embodiment of the present disclosure has been disclosed for illustrative purposes, those skilled in the art will appreciate that various modifications, additions, and substitutions are possible, without departing from the scope and spirit of the present disclosure as disclosed in the accompanying claims.

1. A package structure having an air gap, the package structure comprising:
a first substrate layer;
a second substrate layer provided on top of the first substrate layer and having a signal line printed in a predetermined pattern at a center of an upper surface thereof and a pair of grounds printed in a predetermined pattern at opposite sides of the signal line, respectively;
a third substrate layer provided on top of the signal line and the grounds; and
a fourth substrate layer provided on top of the third substrate layer,
wherein the air gap is formed at a center of the third substrate layer, and
wherein an upper portion of the air gap is in contact with a side of a lower portion of the fourth substrate layer, and a lower portion of the air gap is in contact with the signal line.

2. The package structure of claim 1, wherein the first substrate layer, the second substrate layer, the third substrate layer, and the fourth substrate layer are made of a dielectric material.

3. The package structure of claim 1, further comprising: a ground layer disposed between the first substrate layer and the second substrate layer.

4. The package structure of claim 1, further comprising:
a via provided below at least one of the signal line the grounds,
wherein the via penetrates the first substrate layer and the second substrate layer in a vertical direction.

5. The package structure of claim 1, further comprising: a ground plane printed on a lower surface of the fourth substrate layer.

6. The package structure of claim 1, wherein either a front or a rear surface of the air gap is configured to be opened.
